(19) United States
(12) Patent Application Publication
(10) Pub. No.: US 2026/0168076 A1
(43) Pub. Date: Jun. 18, 2026

(54) DEPOSITION EQUIPMENT FOR DISPLAY DEVICES, ELECTRONIC DEVICE AND METHOD OF DEPOSITION FOR DISPLAY DEVICE

(71) Applicants: SAMSUNG DISPLAY CO., LTD., YONGIN-SI (KR); ULVAC, INC., Chigasaki-shi (JP)

(72) Inventors: Kyung Hoon CHUNG, Yongin-si (KR); Hironori WAKAMATSU, Chigasaki-shi (JP); Masao NISHIGUCHI, Chigasaki-shi (JP); Shuji SHIMIZU, Chigasaki-shi (JP); Jung Seob LEE, Yongin-si (KR); Yong Sic JEON, Yongin-si (KR); Hyeon Sik KIM, Yongin-si (KR); Yong YEO, Yongin-si (KR); Hideki IIJIMA, Chigasaki-shi (JP); Kazuhiko KOIZUMI, Chigasaki-shi (JP); Shinjiro KURAHASHI, Chigasaki-shi (JP)

(21) Appl. No.: 19/289,169

(22) Filed: Aug. 4, 2025

(30) Foreign Application Priority Data
Dec. 12, 2024 (KR) 10-2024-0184331

(51) Int. Cl. C23C 14/04; H10K 71/16

(52) U.S. Cl. CPC C23C 14/042; H10K 71/166

(57) ABSTRACT

A deposition equipment for display devices includes a chamber including a first gate and a second gate. A deposition source is disposed in the chamber. A stage is disposed on the deposition source. A mask structure is disposed on the stage. The mask structure includes a frame and a mask disposed on the frame. A driving mechanism is disposed on the mask structure. A transfer track has a first portion disposed inside the chamber and a second portion disposed outside the chamber. The transfer track extends through the first gate of the chamber and the second gate of the chamber. A first adsorption area of a first surface of the frame adsorbed by the driving mechanism and a second adsorption area of an opposite second surface of the frame adsorbed by the stage at least partially overlap each other.

### CROSS-REFERENCE TO RELATED APPLICATION

This application claims priority under 35 U.S.C. § 119 to Korean Patent Application No. 10-2024-0184331, filed on Dec. 12, 2024 in the Korean Intellectual Property Office, the disclosure of which is incorporated by reference in its entirety herein.

### 1. Technical Field

The present disclosure relates to a deposition equipment for display devices, and more particularly, to a deposition equipment for display devices, an electronic device, and a method of deposition for a display device in which film formation precision may be increased.

### 2. Discussion of Related Art

Organic light emitting diode displays have self-luminous properties and do not require separate light sources unlike liquid crystal displays. Therefore, organic light emitting diode displays may have a reduced thickness and weight. In addition, the organic light emitting diode displays have attracted attention as next-generation display devices for portable electronic devices because they exhibit high-quality characteristics such as low power consumption, high luminance, and a high response speed.

### SUMMARY

Aspects of the present disclosure provide a deposition equipment for display devices, an electronic device, and a method of deposition for a display device in which film formation precision may be increased.

According to an embodiment of the present disclosure, a deposition equipment for display devices includes a chamber including a first gate and a second gate. A deposition source is disposed in the chamber. A stage is disposed on the deposition source. A mask structure is disposed on the stage. The mask structure includes a frame and a mask disposed on the frame. A driving mechanism is disposed on the mask structure. A transfer track has a first portion disposed inside the chamber and a second portion disposed outside the chamber. The transfer track extends through the first gate of the chamber and the second gate of the chamber. A first adsorption area of a first surface of the frame adsorbed by the driving mechanism and a second adsorption area of an opposite second surface of the frame adsorbed by the stage at least partially overlap each other.

According to an embodiment of the present disclosure, a method of deposition for a display device includes disposing a deposition source, a stage, a driving mechanism, a pusher, and a transfer track inside a chamber between a first inner wall of a chamber and a second inner wall of the chamber. A carrier loaded with a mask structure including a mask is moved along the transfer track to load the carrier into the chamber. A first adsorption area of a frame of the mask structure is adsorbed by a first electromagnet of the driving mechanism. The mask structure is decoupled from the carrier. The driving mechanism that the mask structure is attached thereto moves towards the stage. A second adsorption area of the frame of the mask structure is adsorbed by a second electromagnet of the stage. The first adsorption area of the frame and the second adsorption area of the frame at least partially overlap each other.

According to an embodiment of the present disclosure, an electronic device includes a display device. A substrate of the display device includes an organic material formed using a deposition equipment. The deposition equipment includes a chamber. A deposition source is disposed in the chamber. A stage is disposed on the deposition source. A mask structure is disposed on the stage. The mask structure includes a frame and a mask disposed on the frame. A driving mechanism is disposed on the mask structure. A transfer track has a first portion disposed inside the chamber and a second portion disposed outside the chamber. The transfer track extends through the first gate of the chamber and the second gate of the chamber. The mask structure includes a frame and a mask disposed on the frame. A first adsorption area of a first surface of the frame adsorbed by the driving mechanism and a second adsorption area of an opposite second surface of the frame adsorbed by the stage at least partially overlap each other.

With a deposition equipment for display devices, an electronic device, and a method of deposition for a display device, film formation precision of the deposition equipment may be increased.

For example, positions of first adsorption areas when a mask structure is adsorbed through zero electromagnets of a driving mechanism and positions of second adsorption areas when the mask structure is adsorbed through zero electromagnets of a stage may be substantially the same as each other. Therefore, a deviation between a position of a mask before the mask structure is installed on the stage and a position of the mask after the mask structure is installed on the stage may be minimized. Accordingly, an alignment degree between a substrate and the mask may be increased. Accordingly, alignment accuracy between pixels of the substrate and pattern holes of the mask may be increased, such that film formation precision may be increased.

In addition, when a conveyance member in a carrier is attached to the driving mechanism, the carrier is supported by a pusher and a lower track, and thus, a weight of the carrier may not be transmitted to the driving mechanism. Accordingly, a fatigue degree of the driving mechanism in an adsorption process of the conveyance member may be reduced.

The effects of the present disclosure are not limited to the above-described effects and other effects which are not described herein will become apparent to those skilled in the art from the following description.

### BRIEF DESCRIPTION OF THE DRAWINGS

The above and other aspects and features of the present disclosure will become more apparent by describing in detail non-limiting embodiments thereof with reference to the attached drawings, in which:

FIG. 1 is a schematic view of a deposition equipment according to an embodiment of the present disclosure;

FIG. 2 is a perspective view of a mask structure of FIG. 1 according to an embodiment of the present disclosure;

FIG. 3 is a perspective view of a stage and a frame of FIG. 1 according to an embodiment of the present disclosure;

FIG. 4 is a view for describing a situation before the frame is coupled to the stage of FIG. 3 according to an embodiment of the present disclosure;

FIG. 5 is a perspective view of a first carrier disposed on a transfer track according to an embodiment of the present disclosure;

FIG. 6 is an enlarged view of area A1 of FIG. 5 according to an embodiment of the present disclosure;

FIG. 7 is a view for describing that the mask structure is coupled to the first carrier of FIG. 5 according to an embodiment of the present disclosure;

FIG. 8 is an enlarged view of area A2 of FIG. 7 according to an embodiment of the present disclosure;

FIGS. 9 to 12 are views for describing decoupling between the first carrier and the mask structure according to embodiments of the present disclosure;

FIG. 13 is a perspective view of a substrate tray of FIG. 1 according to an embodiment of the present disclosure;

FIG. 14 is a view for describing that the substrate tray of FIG. 13 is coupled to a second carrier according to an embodiment of the present disclosure;

FIGS. 15 to 22 are views for describing a method of deposition of the deposition equipment according to embodiments of the present disclosure;

FIG. 23 is a block diagram of an electronic device according to an embodiment of the present disclosure; and

FIGS. 24 to 26 are schematic views of electronic devices according to various embodiments of the present disclosure.

### DETAILED DESCRIPTION OF EMBODIMENTS

The present invention will now be described more fully hereinafter with reference to the accompanying drawings, in which non-limiting embodiments of the present disclosure are shown. The present disclosure may, however, be embodied in different forms and should not be construed as limited to the described embodiments set forth herein.

It will also be understood that when a layer is referred to as being “on” another layer or substrate, it can be directly on the other layer or substrate, or intervening layers may also be present. When a layer is referred to as being “directly on” another layer or substrate, no intervening layers may be present. The same reference numbers indicate the same components throughout the specification. In the attached figures, the thickness of layers and regions may be exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, technically various interactions and operations are possible. Various embodiments can be practiced individually or in combination.

Hereinafter, specific non-limiting embodiments will be described with reference to the accompanying drawings.

The present disclosure concerns deposition equipment for display devices in which a first carrier may be a conveyance means for loading a mask structure into a chamber and a second carrier may be a conveyance means for loading a substrate tray into the chamber. The mask structure includes a frame having a first surface including a first adsorption area releasably adsorbed by a driving mechanism and an opposite second surface having a second adsorption area releasably adsorbed by a stage. The first adsorption area and the second adsorption area at least partially overlap each other. Therefore, a position of a mask before the mask structure is installed on the stage and a position of the mask after the mask structure is installed on the stage may be substantially the same to increase alignment accuracy between the substate and the mask.

The deposition equipment increases the alignment accuracy between pixels of the substrate and the pattern holes of the mask as well as the accuracy of the film formation. Furthermore, a fatigue degree of the driving mechanism may be reduced by bearing the weight of the mask structure and the substrate tray by the first carrier and second carrier, respectively, when the mask structure and the substrate tray are released.

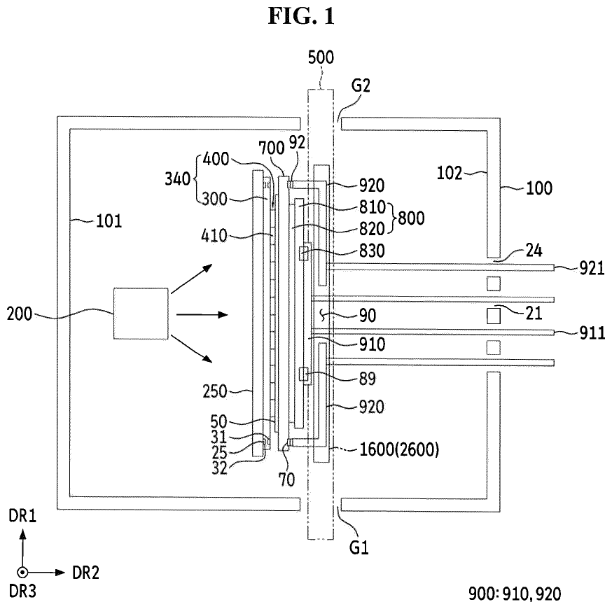

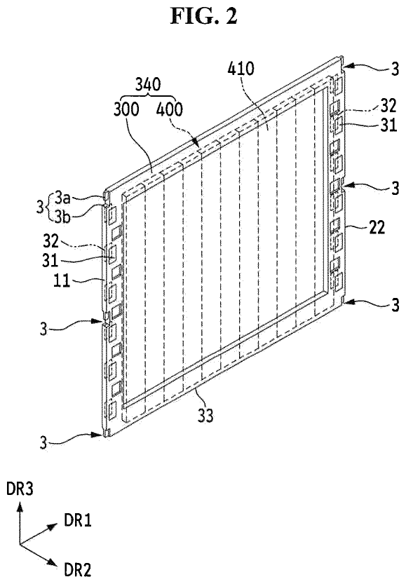

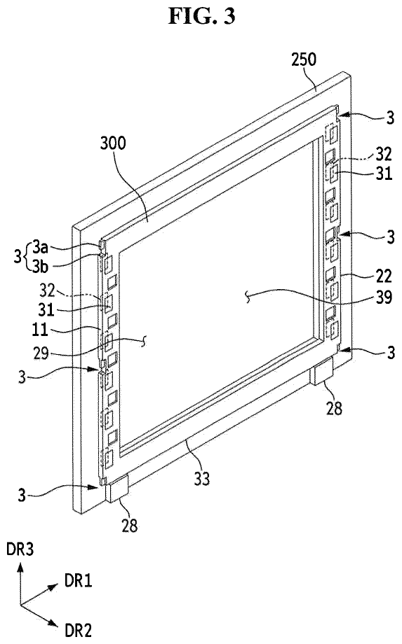

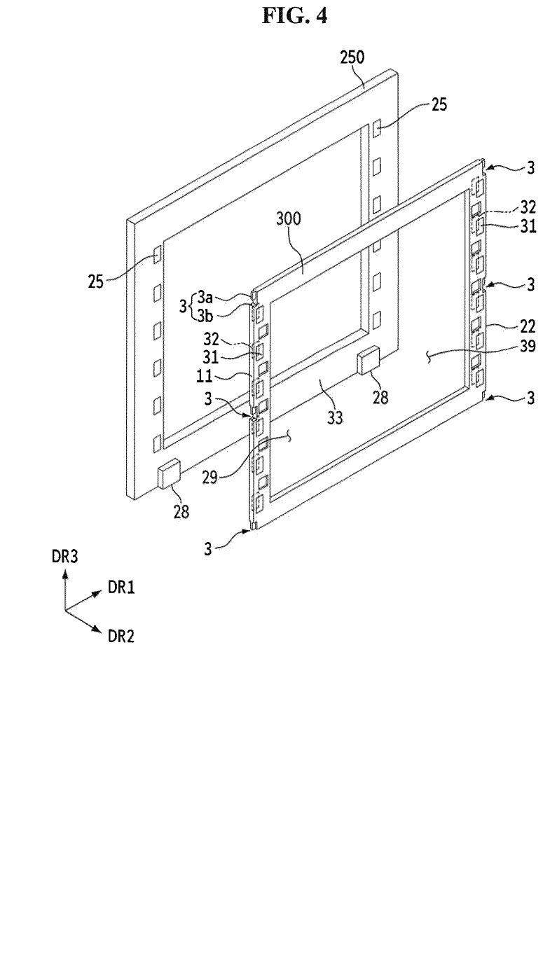

FIG. 1 is a schematic view of a deposition equipment according to an embodiment, FIG. 2 is a perspective view of a mask structure of FIG. 1, FIG. 3 is a perspective view of a stage and a frame of FIG. 1, and FIG. 4 is a view for describing a situation before the frame is coupled to the stage of FIG. 3. In FIGS. 1 to 4, a reverse direction of a third direction DR3 (hereinafter referred to as a third reverse direction) may be a gravity direction. The third direction DR3 may be a direction opposite to the pull of gravity, such as an upward direction.

The deposition equipment for a display device according to an embodiment may include a chamber 100, a deposition source 200, a stage 250, a mask structure 340 (e.g., a mask assembly), a substrate tray 700, a magnet plate 800, a transfer track 500, a first carrier 1600, and a driving mechanism 900 (e.g., a driver), as illustrated in FIG. 1.

The chamber 100 may define a deposition space therein. Here, the deposition space may be a space in which a deposition process is performed. For example, in an embodiment a film deposition process for manufacturing an organic light emitting diode display may be performed inside the chamber 100. In an embodiment, the chamber 100 may be a vacuum chamber 100. The deposition source 200, the stage 250, the driving mechanism 900, and a portion of the transfer track 500 described above may be disposed in the chamber 100. In an embodiment, when the deposition process is being performed, the deposition source 200, the stage 250, the mask structure 340, a substrate 50, the substrate tray 700, the magnet plate 800, a portion of the transfer track 500, and the driving mechanism 900 may be disposed inside the chamber 100.

The deposition source 200 may be disposed inside the chamber 100. For example, in an embodiment the deposition source 200 may be disposed between a first inner wall 101 of the chamber 100 and the stage 250 (e.g., in the second direction DR2). The deposition source 200 may provide a deposition material. The deposition material from the deposition source 200 may pass through an opening 29 of the stage 250 and then move towards the mask structure 340. In an embodiment, the deposition source 200 heats and evaporates a deposition material such as an organic material or an electrode material to a high temperature (e.g., 500° C. or more, 1000° C. or more, 2000° C. or more, etc.), and the evaporated deposition material may be deposited on the substrate 50 through a pattern hole of the mask structure 340. In an embodiment, the above-described organic material may be, for example, a material for manufacturing a hole injection layer, a hole transport layer, a light emitting layer, an electron transport layer, and an electron injection layer disposed between an anode electrode and a cathode electrode of an organic light emitting diode. In an embodiment, the substrate 50 may be, for example, a substrate used in a display device including the organic light emitting diodes.

The stage 250 may be disposed on the deposition source 200. For example, the stage 250 may be disposed between the deposition source 200 and the mask structure 340 (e.g., in the second direction DR2). The stage 250 may be disposed in a fixed state inside the chamber 100. In an embodiment, the stage 250 may have a state in which it is inclined towards the deposition source 200. For example, in an embodiment the stage 250 may be disposed to be inclined in a second reverse direction of a second direction DR2 based on the third direction DR3. Accordingly, an angle formed between one surface of the stage 250 facing the deposition source 200 and a ground surface (e.g., a bottom surface of the chamber 100) on which the stage 250 is disposed may be an acute angle. In an embodiment, the stage 250 may have a shape of a rectangular frame of which a central portion is penetrated. For example, the stage 250 may have the opening 29 at the central portion. However, embodiments of the present disclosure are not necessarily limited thereto and the stage 250 may have various different shapes. As illustrated in FIGS. 1 and 4, the stage 250 may include a zero electromagnet 25. A zero electromagnet 25 may be an electromagnet that generates magnetic force when there is no electrical current applied to the zero electromagnet. For example, the zero electromagnet 25 may be disposed on one surface of the stage 250. According to an embodiment, a plurality of zero electromagnets 25 may be disposed on one surface of the stage 250 facing the mask structure 340. In an embodiment, the plurality of zero electromagnets 25 may be disposed on one surface of the stage 250 facing a frame 300 of the mask structure 340 (e.g., in the second direction DR2). The plurality of zero electromagnets 25 may correspond to (e.g., overlap with) an adsorption area of the frame 300 where the frame 300 is adsorbed to the stage 250. In this case, the zero electromagnets 25 of the stage 250 may be disposed on both edges of one surface of the stage 250. In some embodiments, the stage 250 may include a conventional electromagnet instead of the zero electromagnet 25.

On the lower side of the stage 250 (e.g., in the third reverse direction), pedestals 28 protruding from one surface of the lower side along the second direction DR2 may be disposed. The respective pedestals 28 may be disposed to face each other in a first direction DR1. In an embodiment, the stage 250 may have a shape of a rectangular frame of which a central portion is penetrated. Each of the pedestals 28 may ascend and descend along the third direction DR3 and the third reverse direction.

The mask structure 340 may be disposed on the stage 250. For example, the mask structure 340 may be disposed between the stage 250 and the substrate tray 700 (e.g., in the second direction DR2). The mask structure 340 may be disposed on the pedestals 28 of the stage 250. In an embodiment in which the stage 250 is inclined, the mask structure 340 may be disposed in an inclined state on the stage 250. The mask structure 340 may include the frame 300 and a mask 400.

The frame 300 may be disposed on the stage 250. For example, the frame 300 may be disposed between the stage 250 and the mask 400 (e.g., in the second direction DR2). In an embodiment, the frame 300 may have a shape of a rectangular frame of which a central portion is penetrated. For example, the frame 300 may have an opening 39 at the central portion. However, embodiments of the present disclosure are not necessarily limited thereto and the frame 300 may have various different shapes.

As illustrated in FIG. 3, a first groove 31 and a second groove 32 may be disposed on both edges of the frame 300. For example, the first groove 31 may define a first adsorption area of the mask structure 340 (e.g., the frame 300), and the second groove 32 may define a second adsorption area of the mask structure 340 (e.g., the frame 300). For example, the first groove 31 may be the first adsorption area of the frame 300, and the second groove 32 may be the second adsorption area of the frame 300.

The first grooves 31 and the second grooves 32 may be disposed on one surface (e.g., a first surface) and the other surface (e.g., an opposite second surface) of the frame 300, respectively, so as to overlap each other (e.g., in the second direction DR2). For example, a plurality of first grooves 31 may be disposed on both edges of one surface (e.g., a first surface) of the frame 300, and a plurality of second grooves 32 may be disposed on both edges of the other surface (e.g., a second surface) of the frame 300. Here, one surface (e.g., a first surface) of the frame 300 may be a surface on which the mask 400 is disposed and which faces the substrate tray 700 and the driving mechanism 900 (e.g., in the second direction), and the other surface (e.g., a second surface) of the frame 300 may be a surface positioned on a side opposite to one surface (e.g., the first surface) of the frame 300 and which faces the deposition source 200 and the stage 250 (e.g., in the second reverse direction). One surface (e.g., the first surface) and the other surface (e.g., a second surface) of the frame 300 may face each other in the second direction DR2.

The first groove 31 and the second groove 32 of the frame 300 may face each other in a thickness direction of the frame 300 (e.g., the second direction DR2). The first groove 31 and the second groove 32 may at least partially overlap each other (e.g., in the second direction DR2). For example, the first groove 31 and the second groove 32 disposed to correspond to each other may at least partially overlap each other in the thickness direction of the frame 300 (e.g., the second direction DR2). According to an embodiment, the entirety of the first groove 31 and the entirety of the second groove 32 disposed to correspond to each other may overlap each other. In an embodiment, the first groove 31 and the second groove 32 of the frame 300 may have the same size as each other (e.g., same volume in the first, second and third directions DR1, DR2, DR3 and/or same area in the first and third directions DR1, DR3).

The first groove 31 of the frame 300 may have a shape in which it is recessed from one surface (e.g., the first surface) of the frame 300 towards the other surface (e.g., the second surface) of the frame 300. The second groove 32 of the frame 300 may have a shape in which it is recessed from the other surface (e.g., the second surface) of the frame 300 towards one surface (e.g., the first surface) of the frame 300.

The first groove 31 of the frame 300 may be disposed to face a second driving mechanism 920 within the chamber 100 (e.g., in the second direction DR2), and the second groove 32 of the frame 300 may be disposed to face the stage 250 within the chamber 100 (e.g., in the second reverse direction). For example, the first groove 31 of the frame 300 may be disposed to face a zero electromagnet 92 of the second driving mechanism 920 within the chamber 100, and the second groove 32 of the frame 300 may be disposed to face the zero electromagnet 25 of the stage 250 within the chamber 100. In an embodiment, the frame 300 may be attached to the stage 250 by magnetic force from the zero electromagnet 25 of the stage 250. In this case, the zero electromagnet 25 of the stage 250 may be disposed in the second groove 32 of the frame 300. In addition, in an embodiment the frame 300 may be attached to the second driving mechanism 920 by magnetic force from the zero electromagnet 92 of the second driving mechanism 920. In this case, the zero electromagnet 92 of the second driving mechanism 920 may be disposed in the first groove 31 of the frame 300.

The frame 300 may include a magnetic material. For example, the frame 300 may include a material (e.g., iron (Fe)) that may be attached to a magnet.

As illustrated in FIG. 3, in an embodiment at least one detachable member 3 may be disposed at an edge of the frame 300. For example, in an embodiment the detachable member 3 may be disposed near each corner of the frame 300 having a rectangular shape. In an embodiment, the frame 300 may have six detachable members 3. Three detachable members 3 of the six detachable members 3 may be disposed on an upper side, a central side, and a lower side of a first side 11 of the frame 300, respectively, and the other three detachable members 3 of the six detachable members 3 may be disposed on an upper side, a central side, and a lower side of a second side 22 of the frame 300, respectively. The first side 11 and the second side 22 of the frame 300 may be disposed to face each other along the first direction DR1. However, embodiments of the present disclosure are not necessarily limited thereto and the number of the detachable members and the arrangement thereof may vary.

In an embodiment, the detachable member 3 may include a coupling tip 3a and a decoupling groove 3b disposed adjacent to each other in the third direction DR3. The coupling tip 3a may be disposed above the decoupling groove 3b. For example, in one detachable member 3, the coupling tip 3a may be disposed above the decoupling groove 3b in the third direction DR3. In an embodiment, the coupling tip 3a may have a smaller thickness (e.g., a size in the second direction DR2) than other portions of the frame 300. The decoupling groove 3b may have a shape in which it is recessed from the first side 11 of the frame 300 towards the second side 22 of the frame 300 or a shape in which it is recessed from the second side 22 of the frame 300 towards the first side 11 of the frame 300. For example, the decoupling grooves 3b disposed on different sides and facing each other may have shapes in which they are recessed towards each other.

The mask 400 may be disposed on the frame 300 (e.g., in the second direction DR2). For example, the mask 400 may be disposed between the frame 300 and the substrate tray 700 (e.g., in the second direction DR2). The mask 400 may be disposed on the frame 300 so as to cover the opening 39 of the frame 300. Edges of the mask 400 may be attached to (e.g., attached directly thereto) the frame 300. For example, in an embodiment the mask 400 may be attached to the frame 300 by a welding method. In an embodiment, the mask 400 may be a fine metal mask (FMM).

The mask 400 may include a plurality of sub-masks 410 (or mask sticks). In an embodiment, each of the sub-masks 410 may have a rectangular shape in which it extends in the third direction DR3. The sub-masks 410 may be arranged along the first direction DR1. Adjacent sub-masks 410 may be in direct contact with each other. A portion of each sub-mask 410 excluding both edges may be disposed on the opening 39 of the frame 300. In an embodiment, each sub-mask 410 may have a plurality of pattern holes penetrating through each sub-masks 410 in the second direction DR2. The deposition material from the deposition source 200 may be deposited on the substrate 50 through the pattern holes of each sub-mask 410. Each sub-mask 410 may be made of a material including a magnetic material (e.g., iron (Fe)). For example, each sub-mask 410 may include a material attached to a magnet.

The substrate tray 700 may be disposed on the mask structure 340 (e.g., in the second direction DR2). For example, the substrate tray 700 may be disposed between the mask 400 of the mask structure 340 and the magnet plate 800 (e.g., in the second direction DR2). The substrate tray 700 may transfer the substrate 50. In this case, the substrate tray 700 may adsorb the substrate 50 by electrostatic force. For example, the substrate tray 700 may provide a surface on which the substrate 50 is disposed, and may serve as an electrostatic chuck adsorbing and fixing the substrate 50 to one surface (e.g., a first surface) of the substrate tray 700. In an embodiment, the substrate tray 700 may be made of a material including ceramic or titanium.

The magnet plate 800 may be disposed on the substrate tray 700. For example, the magnet plate 800 may be disposed between the substrate tray 700 and the driving mechanism 900 (e.g., in the second direction DR2). The magnet plate 800 may be disposed on the substrate tray 700 so as to face the substrate tray 700. The magnet plate 800 may provide magnetic force. For example, the magnet plate 800 may provide the magnetic force so that the above-described mask 400 made of a metal material is in close contact with the substrate 50.

In an embodiment, the magnet plate 800 may include a base member 810 and a plurality of magnets 820 disposed on the base member 810. For example, the magnets 820 may be disposed on (e.g., disposed directly thereon) the base member 810. In an embodiment, when one surface of the base member 810 facing the substrate tray 700 (e.g., in the second reverse direction) is defined as a first surface of the base member 810, the magnets 820 may be disposed on (e.g., disposed directly thereon) the first surface of the base member 810. Each magnet 820 may include, for example, a permanent magnet.

The magnet 820 may have a N pole and a S pole. In an embodiment, the plurality of magnets 820 disposed along the first direction DR1 may be disposed so that opposite polarities face each other in the first direction DR1. The plurality of magnets 820 disposed along the second direction DR2 may be disposed so that opposite polarities face each other.

In an embodiment in which a surface of the base member 810 opposite the first surface of the base member 810 (e.g., in the second direction DR2) is defined as a second surface of the base member 810, a plurality of magnetic bodies 830 may be disposed on the second surface of the base member 810. For example, the plurality of magnetic bodies 830 may be disposed in coupling grooves of the base member 810 on the second surface. For example, in an embodiment the magnetic body 830 may include a material (e.g., iron (Fe)) that may be attached to a magnet.

In an embodiment, the driving mechanism 900 may include a first driving mechanism 910 and the second driving mechanism 920.

The first driving mechanism 910 may be disposed between the magnet plate 800 and the second driving mechanism 920 (e.g., in the second direction DR2). For example, the first driving mechanism 910 may be disposed between the base member 810 of the magnet plate 800 and the second driving mechanism 920 (e.g., in the second direction DR2). A first driving shaft 911 may be connected to (e.g., directly connected thereto) one side of the first driving mechanism 910. The first driving mechanism 910 may include a magnet 89. For example, the magnet 89 may be disposed on a surface opposite to a surface of the first driving mechanism 910 connected to the first driving shaft 911. The magnets 89 of the first driving mechanism 910 may be disposed to correspond to (e.g., overlap in the second reverse direction) the magnetic bodies 830 of the magnet plate 800. The magnet 89 may include a permanent magnet. The first driving mechanism 910 may move in the second direction DR2 and a reverse direction of the second direction DR2 (hereinafter referred to as a second reverse direction) by the movement of the first driving shaft 911. In addition, the first driving mechanism 910 may move along the first direction DR1, a reverse direction of the first direction DR1 (hereinafter referred to as a first reverse direction), the third direction DR3, and a reverse direction of the third direction DR3 (hereinafter referred to as a third reverse direction). In addition, the first driving mechanism 910 may rotate around the first driving shaft 911. For example, the first driving mechanism 910 may rotate from the third direction DR3 to the first direction DR1 and from the third direction DR3 to the first reverse direction.

In an embodiment, the magnet plate 800 may be detachably attached to the first driving mechanism 910. For example, the base member 810 of the magnet plate 800 may be detachably attached to the magnet 89 of the first driving mechanism 910. For example, the magnetic body 830 of the base member 810 may be attached to the magnet 89 of the first driving mechanism 910 by magnetic force from the magnet 89 of the first driving mechanism 910. In an embodiment, the first driving shaft 911 may be connected to an external driving unit through a hole 90 of the second driving mechanism 920 and a hole 21 of the chamber 100. The movement of the magnet plate 800 attached to the first driving mechanism 910 may be controlled by the movement of the first driving mechanism 910. For example, the magnet plate 800 may move in the same direction as the first driving mechanism 910.

The second driving mechanism 920 may be disposed between the first driving mechanism 910 and a second inner wall 102 of the chamber 100 (e.g., in the second direction DR2). The second driving mechanism 920 may include the zero electromagnet 92. The zero electromagnet 92 may correspond to (e.g., overlap with) an adsorption area of the frame 300 where the frame is adsorbed to the driving mechanism 900. The substrate tray 700 may be attached to the second driving mechanism 920. For example, a magnetic body 70 of the substrate tray 700 is attached to the zero electromagnet 92 of the second driving mechanism 920, such that the substrate tray 700 may be attached to the second driving mechanism 920. In an embodiment, the zero electromagnets 92 may be disposed at both edges of the second driving mechanism 920. The magnetic bodies 70 may be disposed at both edges of the substrate tray 700 so as to correspond to (e.g., overlap with in the second direction DR2) the zero electromagnets 92. The magnetic body 70 may include a magnetic material attached to a magnet, such as iron (Fe). The second driving mechanism 920 may move in the second direction DR2 and the second reverse direction by the movement of a second driving shaft 921. In addition, the second driving mechanism 920 may move along the first direction DR1, the first reverse direction, the third direction DR3, and the third reverse direction. In addition, the second driving mechanism 920 may rotate around the second driving shaft 921. For example, the second driving mechanism 920 may rotate from the third direction DR3 to the first direction DR1 and from the third direction DR3 to the first reverse direction.

In an embodiment, the second driving mechanism 920 may include an electromagnet instead of the zero electromagnet 92. The second driving mechanism 920 may be connected to (e.g., directly connected thereto) the second driving shaft 921. The movement of the substrate tray 700 attached to the second driving mechanism 920 may be controlled by the movement of the second driving mechanism 920. The second driving mechanism 920 may perform alignment work between the substrate 50 of the substrate tray 700 and the mask structure 340 by controlling a position of the substrate tray 700 attached to the second driving mechanism 920.

The transfer track 500 may be disposed, for example, to have a first portion inside the chamber 100 and a second portion outside the chamber 100 so as to pass through a first gate G1 and a second gate G2 of the chamber 100. For example, the transfer track 500 may extend through the first and second gates G1, G2 in the first direction DR1. The transfer track 500 may extend along the first direction DR1. The first gate G1 and the second gate G2 may be disposed to face each other (e.g., in the first direction DR1).

The first carrier 1600 may move along the transfer track 500. For example, in an embodiment the first carrier 1600 may move along the transfer track 500 in a magnetic levitation manner. The first carrier 1600 may transfer the mask structure 340.

As described above, in an embodiment the stage 250 may have a state in which an upper side thereof is inclined towards the deposition source 200. Accordingly, each of the mask structure 340, the substrate tray 700, the substrate 50, the magnet plate 800, the first driving mechanism 910, the second driving mechanism 920, the transfer track 500, and the carrier 1600 or 2600 described above may also have a state in which it is inclined at the same angle as the stage 250 described above. Accordingly, particles generated during a deposition process for the substrate 50 may fall in the gravity direction without being attached to the substrate 50. Accordingly, contamination of the substrate 50 by the particles may be prevented.

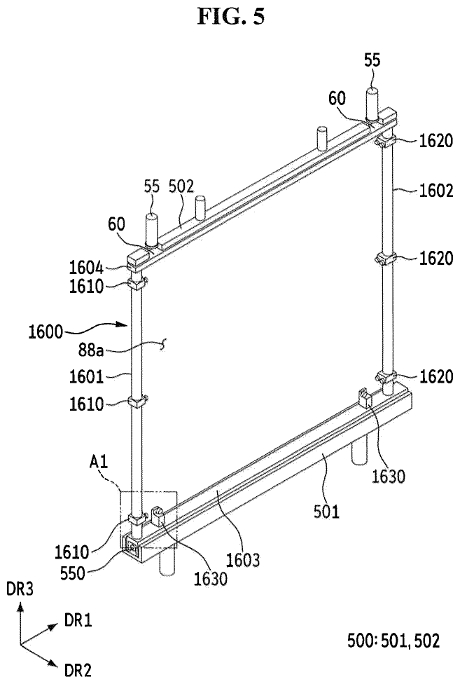

To reduce the complexity of the drawings, the second groove 32 is omitted in FIGS. 5 to 22 to be described later. However, the frame 300 of FIGS. 5 to 22 still includes the second groove 32.

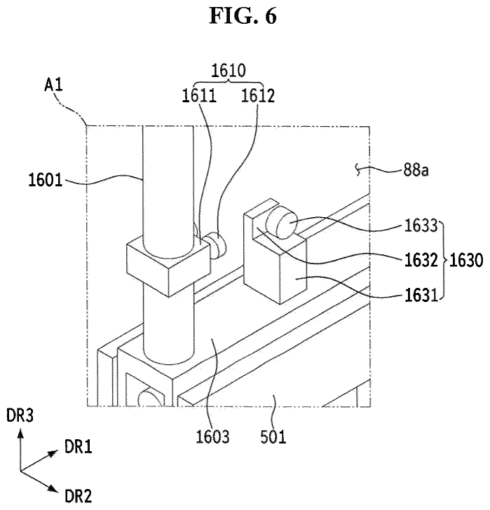

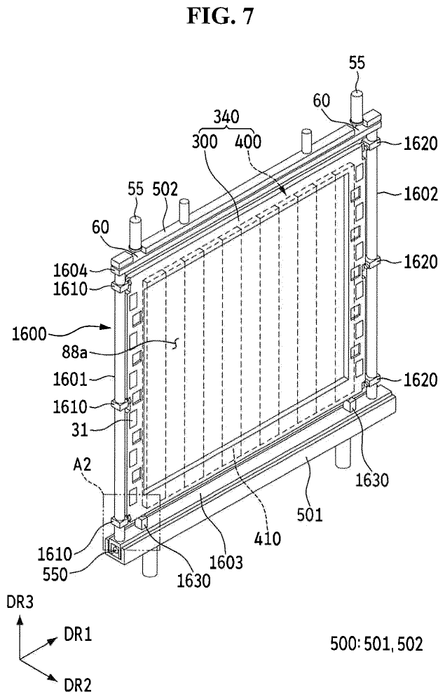

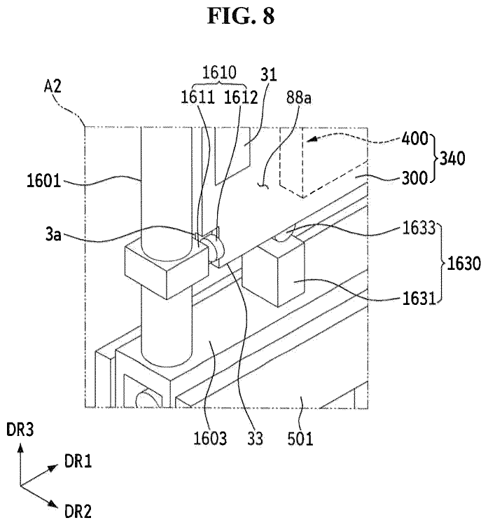

FIG. 5 is a perspective view of a first carrier 1600 disposed on a transfer track 500, FIG. 6 is an enlarged view of area A1 of FIG. 5, FIG. 7 is a view for describing that the mask structure 340 is coupled to the first carrier 1600 of FIG. 5, and FIG. 8 is an enlarged view of area A2 of FIG. 7. Here, FIG. 5 may be a perspective view of the first carrier 1600 disposed on the transfer track 500 of FIG. 1.

The first carrier 1600 may move along the transfer track 500. The transfer track 500 may include a lower track 501 and an upper track 502 disposed to face each other in the third direction DR3. In an embodiment, the lower track 501 may have a U-shaped cross section, and the upper track 502 may have a bar shape cross section. The first carrier 1600 may be disposed between the lower track 501 and the upper track 502 (e.g., in the third direction DR3). The first carrier 1600 may move along the transfer track 500 between the lower track 501 and the upper track 502.

In an embodiment, the first carrier 1600 may have a rectangular frame shape as in an example illustrated in FIG. 5. However, a shape of the first carrier 1600 is not necessarily limited thereto, and may be modified into various shapes.

In an embodiment, the first carrier 1600 may include a plurality of bars 1601, 1602, 1603, and 1604 and a plurality of support members 1610, 1620, and 1630. For example, in an embodiment the first carrier 1600 may include a first bar 1601, a second bar 1602, a third bar 1603, and a fourth bar 1604 connected to each other. The mask structure 340 may be disposed in an area (e.g., an opening 88a) surrounded and defined by the first bar 1601, the second bar 1602, the third bar 1603, and the fourth bar 1604. In an embodiment, the third bar 1603 may have a U-shaped cross-section.

The first bar 1601 and the second bar 1602 may face each other in the first direction DR1. The third bar 1603 and the fourth bar 1604 may face each other in the third direction DR3. The first bar 1601 may be disposed between one end of the third bar 1603 and one end of the fourth bar 1604. The second bar 1602 may be disposed between the other end of the third bar 1603 and the other end of the fourth bar 1604.

The plurality of support members 1610, 1620, and 1630 may include at least one first support member 1610 extending from the first bar 1601, at least one second support member 1620 extending from the second bar 1602, and at least one third support member 1630 extending from the third bar 1603. For example, in an embodiment two first support members 1610 may extend from one side and the other side of the first bar 1601 towards the second bar 1602, respectively. For example, in an embodiment the two first support members 1610 may extend along the first direction DR1 from one side and the other side of the first bar 1601, respectively. Two second support members 1620 may extend from one side and the other side of the second bar 1602 towards the first bar 1601, respectively. For example, the two second support members 1620 may extend along the first reverse direction from one side and the other side of the second bar 1602, respectively. Two third support members 1630 may extend from one side and the other side of the third bar 1603 towards the fourth bar 1604, respectively. For example, the two third support members 1630 may extend along the third direction DR3 from one side and the other side of the third bar 1603, respectively. The two first support members 1610 and the two second support members 1620 may be disposed to face each other, respectively.

As illustrated in FIG. 6, in an embodiment the first support member 1610 may include an extension portion 1611 and a plurality of projections 1612. One side of the extension portion 1611 may be connected to (e.g., directly connected thereto) the first bar 1601. The extension portion 1611 may extend from the first bar 1601 towards the second bar 1602 (e.g., in the first direction DR1). The plurality of projections 1612 (e.g., two projections 1612) may be disposed on the other side of the extension portion 1611. In an embodiment, the plurality of projections 1612 may be rotatably connected to the other side of the extension portion 1611. For example, each of the plurality of projections 1612 may rotate about an axis parallel to the first direction DR1. The plurality of projections 1612, such as two projections 1612 in an embodiment shown in FIGS. 5-6, may be disposed to face each other in the second direction DR2. In an embodiment, each of the plurality of projections 1612 may have a cylindrical shape. However, a shape of each of the projections 1612 is not necessarily limited thereto, and may be modified into various shapes.

The second support member 1620 may have the same configuration as the first support member 1610 described above. However, an extension portion of the second support member 1620 may extend from the second bar 1602 towards the first bar 1601 (e.g., in a first reverse direction).

The third support member 1630 may include an extension portion 1631, a protrusion portion 1632, and a projection 1633. One side (e.g., a lower side in the third reverse direction) of the extension portion 1631 may be connected to (e.g., directly connected thereto) the third bar 1603. The extension portion 1631 may extend from the third bar 1603 towards the fourth bar 1604 (e.g., in the third direction DR3). The protrusion portion 1632 may be disposed on the other side (e.g., an upper side in the third direction DR3) of the extension portion 1631. The projection 1633 may be disposed on one side of the protrusion portion 1632. The projection 1633 may be rotatably connected to one side of the protrusion portion 1632. For example, the projection 1633 may rotate about an axis parallel to the second direction DR2. In an embodiment, the projection 1633 may have a cylindrical shape. However, a shape of the projection 1633 is not necessarily limited thereto, and may be modified into various shapes.

As illustrated in FIGS. 7 and 8, the first support member 1610, the second support member 1620, and the third support member 1630 may support the mask structure 340.

Each of the first support members 1610 may support a first side 11 of the mask structure 340. For example, in an embodiment the first side 11 of the mask structure 340 may be disposed and supported between the projections 1612 of the first support member 1610. In an embodiment, a coupling tip 3a of the first side 11 is disposed between the projections 1612 of the first support member 1610, such that the first side 11 may be supported.

Each of the second support members 1620 may support a second side 22 of the mask structure 340. For example, the second side 22 of the mask structure 340 may be disposed and supported between projections of the second support member 1620. In an embodiment, a coupling tip 3a of the second side 22 is disposed between the projections of the second support member 1620, such that the second side 22 may be supported.

Each of the third support members 1630 may support a third side 33 of the mask structure 340. For example, the third side 33 of the mask structure 340 may be disposed and supported on the projection 1633 of the third support member 1630. In this case, the projection 1633 of the third support member 1630 may be in direct contact with the third side 33.

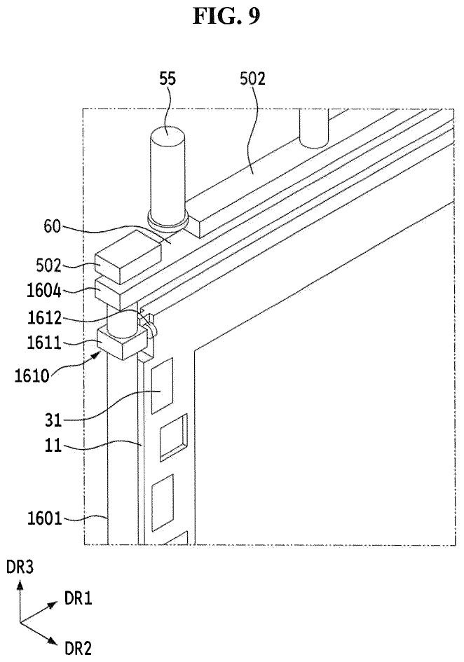

FIGS. 9 to 12 are views for describing decoupling between the first carrier 1600 and the mask structure 340.

The deposition equipment according to an embodiment may further include a pusher 55. The pusher 55 may be disposed on the first carrier 1600. For example, as illustrated in FIG. 9, the pusher 55 may be disposed on (e.g., disposed directly thereon) the fourth bar 1604 of the first carrier 1600. In an embodiment, the pusher 55 may face the fourth bar 1604 through an opening 60 of the upper track 502. The pusher 55 and the opening 60 of the upper track 502 may be disposed in the chamber 100.

The pusher 55 may move in a direction (e.g., the third reverse direction) towards the fourth bar 1604 (e.g., an upper surface of the fourth bar 1604 in the third direction DR3) or move in a direction (e.g., the third direction DR3) opposite to the direction towards the fourth bar 1604. For example, the pusher 55 may move along the third reverse direction or the third direction DR3. The pusher 55 may move along the third reverse direction to a distance of a first stage and a distance of a second stage. Here, the distance of the second stage may be greater than the distance of the first stage.

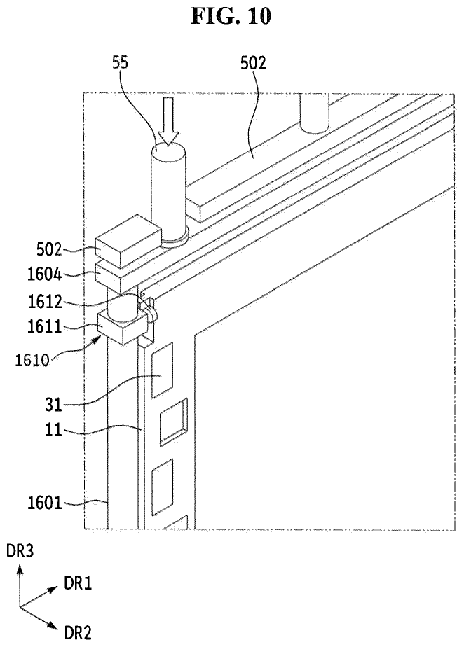

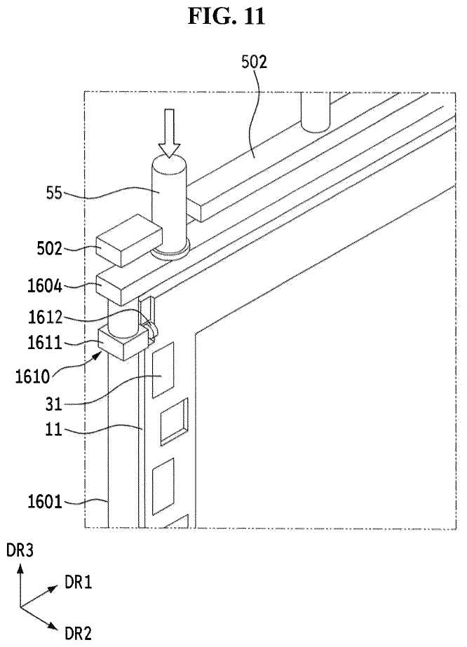

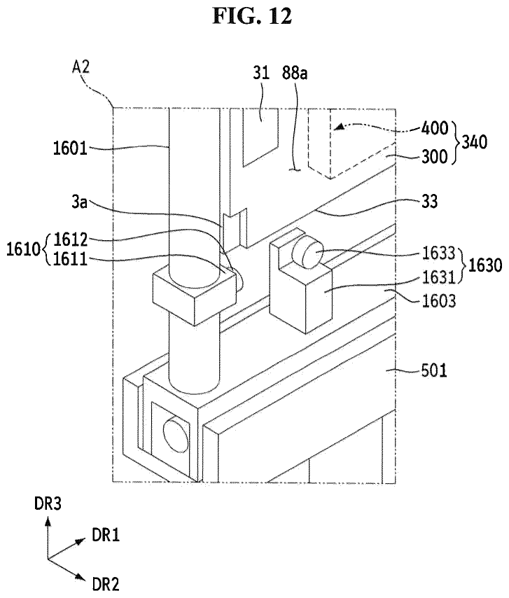

As illustrated in FIG. 10, when the pusher 55 descends to the distance of the first stage along the third reverse direction, the pusher 55 may pass through the opening 60 of the upper track 502 and then come into direct contact with the fourth bar 1604 e.g., an upper surface of the fourth bar 1604). In an embodiment, in a state in which the pusher 55 is in direct contact with the fourth bar, the second driving mechanism 920 may be attached to the mask structure 340 through the zero electromagnet. Thereafter, the pusher may further descend to the distance of the second stage in the state in which it is in direct contact with the fourth bar. For example, as illustrated in FIGS. 11 and 12, the pusher 55 may descend to the distance of the second stage along the third reverse direction. As the pusher 55 descends to the distance of the second stage along the third reverse direction as described above, the first carrier 1600 and the lower track 501 may also descend along the third reverse direction. For example, when the pusher 55 descends to the distance of the second stage, the pusher 55, the first carrier 1600, and the lower track 501 may descend together in the same direction (e.g., the third reverse direction).

When the pusher 55 moves to the distance of the second stage along the third reverse direction, the fourth bar 1604 and the lower track 501 may descend downward by the pressurization of the pusher 55, as illustrated in FIGS. 11 and 12. For example, as the pusher 55 pressurizes the fourth bar 1604 in the third reverse direction, the first carrier 1600 and the lower track 501 may move along the third reverse direction. Accordingly, the first support members 1610, the second support members 1620, and the third support members 1630 may each move in the third reverse direction, and accordingly, the projections 1612 of each first support member 1610 and the projections of each second support member 1620 may be disposed to face each other through the decoupling groove 3b of the mask structure 340. In other words, the projections 1612 of each first support member 1610 and the coupling tip 3a of the first side 11 of the mask structure 340 are not in direct contact with each other, and the projections 1612 of each second support member 1620 and a coupling tip of the second side 22 of the mask structure 340 are not in direct contact with each other. In addition, as the first carrier 1600 descends along the third reverse direction by the pusher 55 as described above, the third support member 1630 and the mask structure 340 may be spaced apart from each other. For example, the projection 1612 of the second support member 1620 and the third side 33 of the mask structure 340 are spaced apart from each other, such that the projection 1633 of the third support member 1630 and the third side 33 are not in direct contact with each other. Accordingly, the mask structure 340 is no longer supported by the first carrier 1600. Accordingly, the mask structure 340 may have a state in which it is easily movable without interference with the first carrier 1600 in the second direction DR2 and the second reverse direction.

In an embodiment, an actuator 550 may be disposed inside the lower track 501. In an embodiment, the actuator 550 may have a screw shape. A plurality of permanent magnets may be disposed on an outer peripheral surface of the actuator 550. In an embodiment, permanent magnets may also be disposed inside the lower track 501, and may also be disposed on each of surfaces of the upper track 502 and the fourth bar 1604 of the first carrier 1600 facing each other. By such permanent magnets and the rotation of the actuator 550, the first carrier 1600 may move along the transfer track 500 in the magnetic levitation manner. For example, a movement direction of the first carrier 1600 disposed on the transfer track 500 may be controlled according to a rotation direction of the actuator 550. In an embodiment, when the actuator 550 rotates in a clockwise direction, the first carrier 1600 may move along the first direction DR1 on the transfer track 500. On the other hand, when the actuator 550 rotates in a counterclockwise direction, the first carrier 1600 may move along the first reverse direction on the transfer track 500.

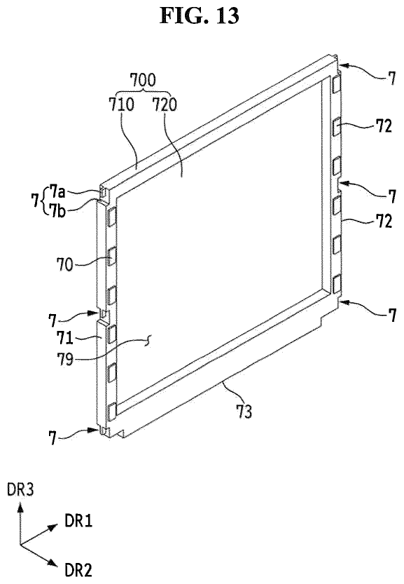

FIG. 13 is a perspective view of a substrate tray 700 of FIG. 1.

As illustrated in FIG. 13, in an embodiment the substrate tray 700 may include a support plate 710 and an electrostatic chuck 720.

In an embodiment, the support plate 710 may have a shape of a rectangular frame of which a central portion is penetrated. For example, the support plate 710 may have an opening 79 at the central portion. However, embodiments of the present disclosure are not necessarily limited thereto and the support plate 710 may have various different shapes.

The electrostatic chuck 720 may be disposed on the support plate 710. For example, the electrostatic chuck 720 may be disposed between the support plate 710 and the substrate 50. In this case, the electrostatic chuck 720 may cover the opening 79 of the support plate 710. The substrate 50 may be disposed on (e.g., disposed directly thereon) the electrostatic chuck 720. In an embodiment, the electrostatic chuck 720 may adsorb the substrate 50 by electrostatic force.

At least one detachable member 7 may be disposed at an edge of the substrate tray 700. For example, in an embodiment the detachable member 7 may be disposed near each corner of the support plate 710 having a rectangular shape. In an embodiment, the support plate 710 may have six detachable members 7. Three detachable members 7 of the six detachable members 7 may be disposed on an upper side, a central side, and a lower side of a first side 71 of the substrate tray 700, respectively, and the other three detachable members 7 of the six detachable members 7 may be disposed on an upper side, a central side, and a lower side of a second side 72 of the substrate tray 700, respectively. The first side 71 and the second side 72 of the substrate tray 700 may be disposed to face each other along the first direction DR1.

In an embodiment, the detachable member 7 may include a coupling tip 7a and a decoupling groove 7b disposed adjacent to each other in the third direction DR3. The coupling tip 7a may be disposed above the decoupling groove 7b. For example, in one detachable member 7, the coupling tip 7a may be disposed above the decoupling groove 7b in the third direction DR3. The coupling tip 7a may have a smaller thickness (e.g., a size in the second direction DR2) than other portions of the substrate tray 700. For example, the coupling tip 7a may have a smaller thickness (e.g., a size in the second direction DR2) than other portions of the support plate 710. The decoupling groove 7b may have a shape in which it is recessed from the first side 71 of the substrate tray 700 (e.g., the support plate 710) towards the second side 72 of the substrate tray 700 or a shape in which it is recessed from the second side 72 of the substrate tray 700 towards the first side 71 of the substrate tray 700. For example, the decoupling grooves 7b disposed on different sides and facing each other may have shapes in which they are recessed towards each other.

According to an embodiment, the detachable members 7 of the substrate tray 700 may have substantially the same structure as the detachable members 3 of the frame 300 provided in the mask structure 340 described above.

A second carrier 2600 may move along the transfer track 500. For example, in an embodiment the second carrier 2600 may move along the transfer track 500 in a magnetic levitation manner. The second carrier 2600 may transfer the substrate tray 700. As described above, according to an embodiment, the first carrier 1600 and the second carrier 2600 may be transferred along the same transfer track 500. Accordingly, according to an embodiment, facilities of the deposition equipment may be simplified, such that a manufacturing cost of the deposition equipment may be reduced.

The above-described second carrier 2600 will be described in detail below.

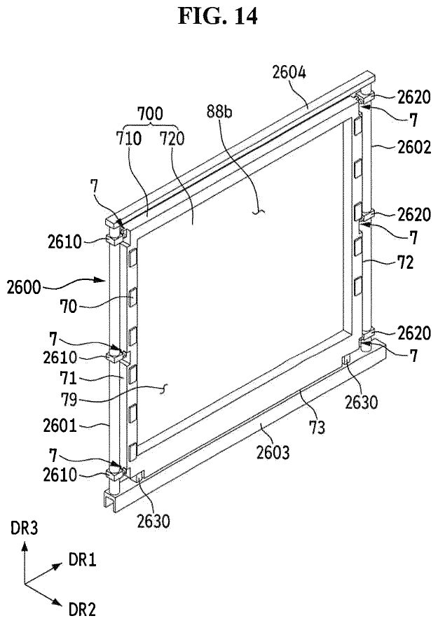

FIG. 14 is a view for describing that the substrate tray 700 of FIG. 13 is coupled to a second carrier 2600.

In an embodiment, the second carrier 2600 may include a plurality of bars 2601, 2602, 2603, and 2604 and a plurality of support members 2610, 2620, and 2630. For example, in an embodiment the second carrier 2600 may include a first bar 2601, a second bar 2602, a third bar 2603, and a fourth bar 2604 connected to each other. The substrate tray 700 may be disposed in an area (e.g., an opening 88b) surrounded and defined by the first bar 2601, the second bar 2602, the third bar 2603, and the fourth bar 2604.

The first bar 2601 and the second bar 2602 may face each other in the first direction DR1. The third bar 2603 and the fourth bar 2604 may face each other in the third direction DR3. The first bar 2601 may be disposed between one end of the third bar 2603 and one end of the fourth bar 2604. The second bar 2602 may be disposed between the other end of the third bar 2603 and the other end of the fourth bar 2604.

The plurality of support members 2610, 2620, and 2630 may include at least one first support member 2610 extending from the first bar 2601 (e.g., in the first direction DR1), at least one second support member 2620 extending from the second bar 2602 (e.g., in the first reverse direction), and at least one third support member 2630 extending from the third bar 2603 (e.g., in the third direction DR3).

The first bar 2601, the second bar 2602, the third bar 2603, the fourth bar 2604, the first support member 2610, the second support member 2620, and the third support member 2630 of the second carrier 2600 are substantially the same as the first bar 1601, the second bar 1602, the third bar 1603, the fourth bar 1604, the first support member 1610, the second support member 1620, and the third support member 1630 of the first carrier 1600 described above, respectively, and thus, reference is made to the description of the first bar 1601, the second bar 1602, the third bar 1603, the fourth bar 1604, the first support member 1610, the second support member 1620, and the third support member 1630 of the first carrier 1600 described above in relation to the first bar 2601, the second bar 2602, the third bar 2603, the fourth bar 2604, the first support member 2610, the second support member 2620, and the third support member 2630 of the second carrier 2600.

In an embodiment, a coupling method between the substrate tray 700 and the second carrier 2600 may be substantially the same as the coupling method between the mask structure 340 and the first carrier 1600 described above.

For example, each of the first support members 2610 of the second carrier 2600 may support the first side 71 of the substrate tray 700. For example, the first side 71 of the substrate tray 700 may be disposed and supported between projections of the first support member 2610. In an embodiment, a coupling tip of the first side 71 is disposed between the projections of the first support member 2610, such that the first side 71 may be supported.

Each of the second support members 2620 may support the second side 72 of the substrate tray 700. For example, the second side 72 of the substrate tray 700 may be disposed and supported between projections of the second support member 2620. In an embodiment, a coupling tip of the second side 72 is disposed between the projections of the second support member 2620, such that the second side 72 may be supported.

Each of the third support members 2630 may support a third side 73 of the substrate tray 700. For example, the third side 73 of the substrate tray 700 may be disposed and supported on a projection of the third support member 2630. In this case, the projection of the third support member 2630 may be in direct contact with the third side 73.

In an embodiment, a decoupling method between the substrate tray 700 and the second carrier 2600 may be substantially the same as the decoupling method between the mask structure 340 and the first carrier 1600 described above. For example, as illustrated in FIGS. 9 to 12 described above, the pusher sequentially descends to the distance of the first stage and the distance of the second stage, such that the substrate tray 700 may be decoupled from the second carrier 2600.

As a specific example, when the pusher 55 moves along the third reverse direction, the pusher 55 may come into direct contact with the fourth bar 2604 of the second carrier 2600 through the opening 60 of the upper track 502. In this case, the fourth bar 2604 may descend downward by the pressurization of the pusher 55. For example, as the pusher 55 pressurizes the fourth bar 2604 in the third reverse direction, the second carrier 2600 may move along the third reverse direction. Accordingly, the first support members 2610, the second support members 2620, and the third support members 2630 may each move in the third reverse direction, and accordingly, the projections of each first support member 2610 and the projections of each second support member 2620 may be disposed to face each other through the decoupling groove 7b of the substrate tray 700. For example, the projections of each first support member 2610 and the coupling tip 7a of the first side 71 of the substrate tray 700 are not in direct contact with each other, and the projections of each second support member 2620 and a coupling tip of the second side 72 of the substrate tray 700 are not in direct contact with each other. In addition, as the second carrier 2600 descends along the third reverse direction by the pusher 55 as described above, the third support member 2630 and the substrate tray 700 may be spaced apart from each other. For example, the projection of the second support member 2620 and the third side 73 of the substrate tray 700 are spaced apart from each other, such that the projection of the third support member 2630 and the third side 73 are not in direct contact with each other. Accordingly, the substrate tray 700 is no longer supported by the second carrier 2600. Accordingly, the substrate tray 700 may have a state in which it is easily movable without interference with the second carrier 2600 in the second direction DR2 and the second reverse direction.

A method of deposition of the deposition equipment according to an embodiment having the configuration as described above will be described in detail below.

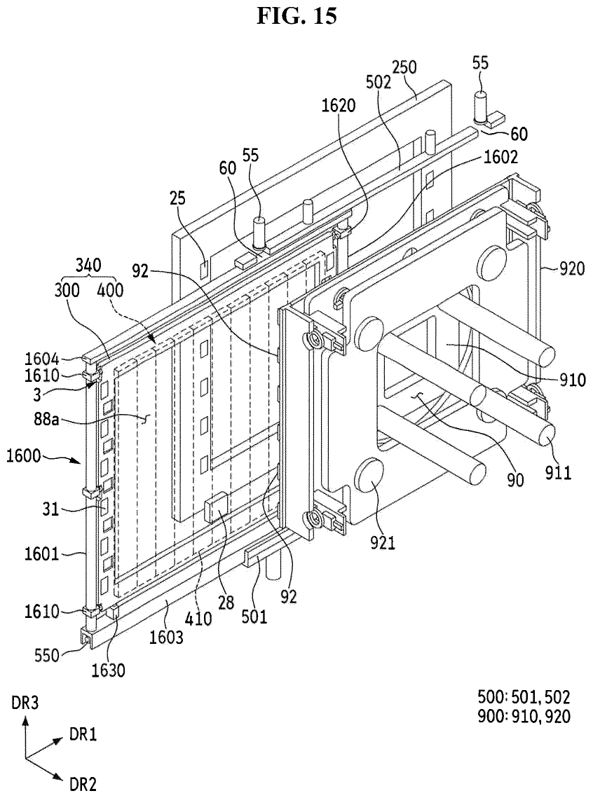

FIGS. 15 to 22 are views for describing a method of deposition of the deposition equipment according to embodiments of the present disclosure.

In an embodiment, the deposition source 200, the stage 250, the first driving mechanism 910, and the second driving mechanism 920 may be disposed inside the chamber 100. In this case, the magnet plate 800 may be attached to the first driving mechanism 910. In addition, the first driving mechanism 910 and the second driving mechanism 920 may be disposed between the transfer track 500 and the second inner wall 102 of the chamber 100 so as not to overlap the transfer track 500.

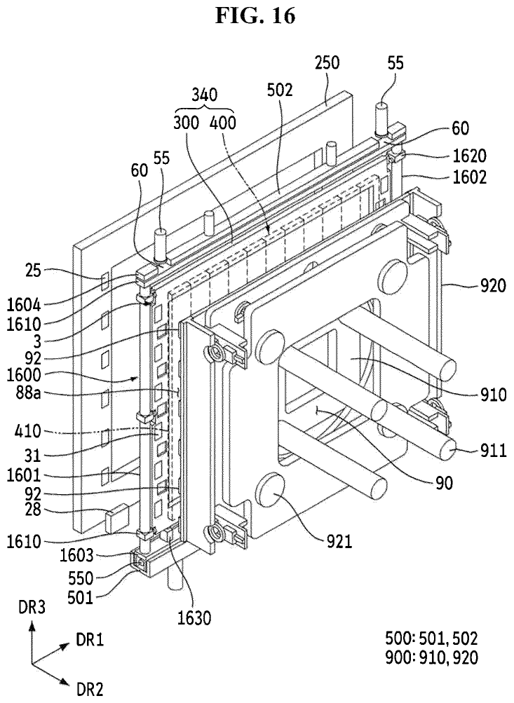

Thereafter, as illustrated in FIG. 15, the first carrier 1600 loaded with the mask structure 340 may be loaded into the chamber 100 along the transfer track 500. For example, in an embodiment the first carrier 1600 loaded with the mask structure 340 may pass through the first gate G1 of the chamber 100 (e.g., in the first direction DR1) along the transfer track 500 and then be loaded into (e.g., disposed inside) the chamber 100. Here, the mask structure 340 may include the frame 300 and the mask 400 attached to the frame 300, and the mask 400 may include the plurality of sub-masks 410. To avoid complexity of the drawings, the mask 400 is omitted in FIGS. 16 to 22. However, the mask structure 340 of FIGS. 16 to 22 still includes the mask 400.

In an embodiment, as illustrated in FIG. 16, the first carrier 1600 may then be disposed in the chamber 100 so that the mask structure 340 is aligned with the stage 250 between the stage 250 and the driving mechanism 900 (e.g., in the second direction DR2).

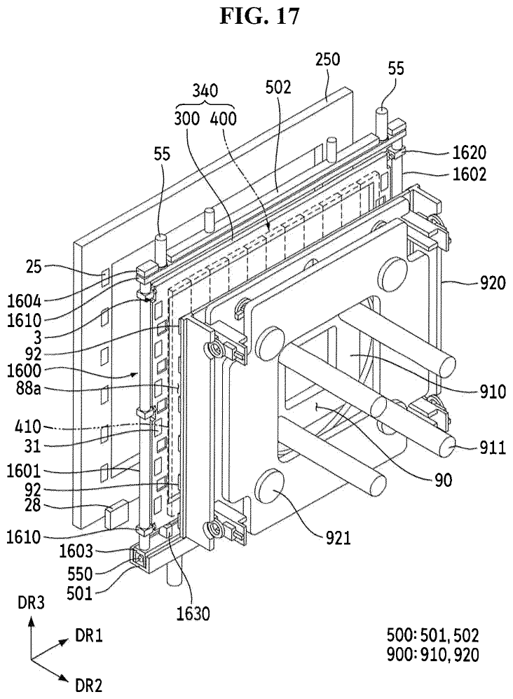

In an embodiment, as illustrated in FIG. 17, the pusher 55 may then descend to the distance of the first stage along the third reverse direction to come into direct contact with the first carrier 1600, such as an upper surface of the fourth bar 1604. In this case, the first carrier 1600 may descend to a predetermined size along the third reverse direction by the pressurization of the pusher 55. In this case, the lower track 501 does not descend and is maintained as it is, such that a gap between the first carrier 1600 and the lower track 501 may be reduced. Accordingly, the first carrier 1600 may be stably disposed on the lower track 501 within the chamber 100. For example, due to the pusher 55 that has descended to the distance of the first stage, the first carrier 1600 may be supported and fixed by the pusher 55 and the lower track 501 between the pusher 55 and the lower track 501. In this case, the first carrier 1600 is supported by the pusher 55 and the lower track 501, and thus, a weight of the first carrier 1600 may not be transmitted to the driving mechanism 900. For example, the driving mechanism 900 may only bear a weight of the mask structure 340 excluding the first carrier 1600. Accordingly, a fatigue degree of the driving mechanism 900 when adsorbing the mask structure 340 may be minimized.

In an embodiment, since a descending distance of the pusher 55 is short when the pusher 55 descends to the distance of the first stage, even though the first carrier 1600 descends by the pressurization of the pusher 55, the mask structure 340 accommodated in the first carrier 1600 may be maintained in a state in which it is supported by the support members 1610, 1620, and 1630 of the first carrier 1600.

Thereafter, the second driving mechanism 920 may recognize a position of the mask structure 340 and adjust an adsorption (or attachment) position between the second driving mechanism 920 and the mask structure 340. For example, an entire position of the driving mechanism 900 including the second driving mechanism 920 may be adjusted for alignment between the zero electromagnet 92 of the second driving mechanism 920 and the first groove 30 of the frame 300.

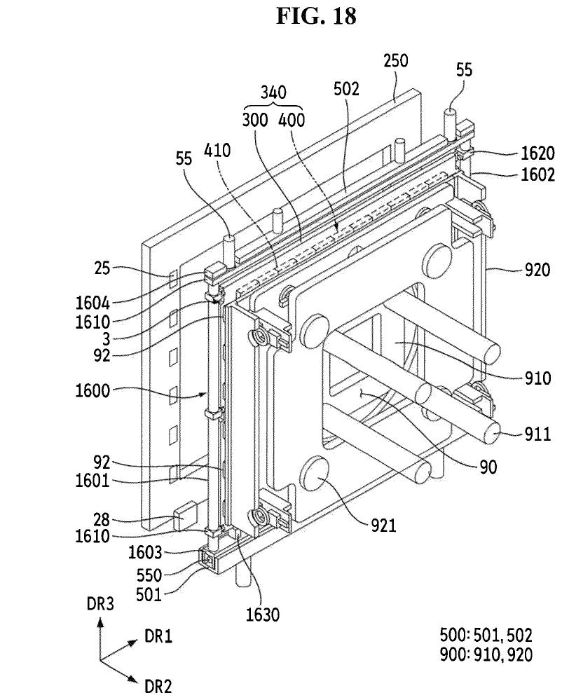

In an embodiment, as illustrated in FIG. 18, the driving mechanism 900 may move towards the first carrier 1600 (e.g., in the second reverse direction). In this case, the zero electromagnet 92 of the second driving mechanism 920 and the frame 300 of the mask structure 340 come into direct contact with each other, and accordingly, the mask structure 340 may be attached to the second driving mechanism 920. For example, after the zero electromagnet 92 of the second driving mechanism 920 is inserted into the first groove 31 of the frame 300, a current applied to the zero electromagnet 92 is removed (or blocked), such that magnetic force may be generated from the zero electromagnet 92, and the mask structure 340 including the frame 300 may be attached to the second driving mechanism 920 by such magnetic force from the zero electromagnet 92. For example, the frame 300 of the mask structure 340 and the mask structure 340 within the first carrier 1600 may be attached to the second driving mechanism 920.

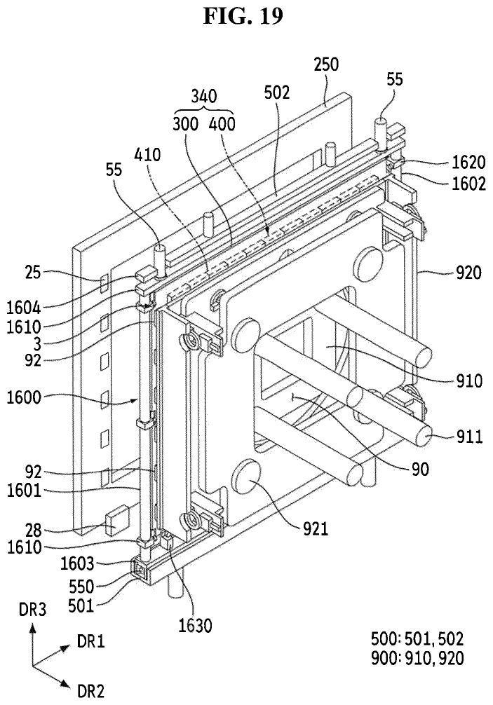

In an embodiment, as illustrated in FIG. 19, in a state in which the mask structure 340 is attached to the second driving mechanism 920, the pusher 55 may further descend to the distance of the second stage, and at the same time, the lower track 501 may descend along the third reverse direction. For example, the pusher 55 and the lower track 501 may descend along the third reverse direction at the same time. Accordingly, the first carrier 1600 and the lower track 501 may further descend along the third reverse direction. In this case, as the pusher 55 descends to the distance of the second stage greater than the distance of the first stage and the lower track 501 descends to a size smaller than the distance of the second stage, a gap between the first carrier 1600 and the upper track 502 may increase, whereas a gap between the first carrier 1600 and the lower track 501 may be substantially the same as the gap between the first carrier 1600 and the lower track 501 when the pusher 55 descends to the distance of the first stage described above. Accordingly, as described above with reference to FIGS. 11 and 12, restraint of the support members 1610, 1620, and 1630 of the first carrier 1600 on the mask structure 340 is removed, and accordingly, the mask structure 340 may be maintained in a state in which it is movable in the second direction DR2 and the second reverse direction from the first carrier 1600. For example, as the second pusher 55 descends to the distance of the second stage, the mask structure 340 attached to the second driving mechanism 920 may be maintained in a free state from the first carrier 1600.

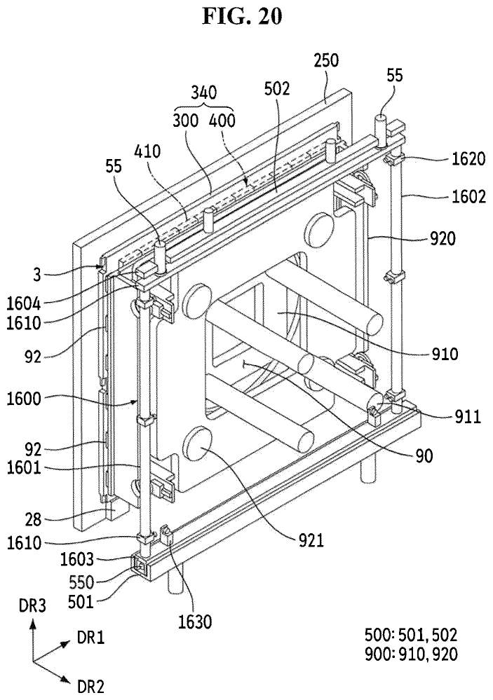

In an embodiment, as illustrated in FIG. 20, the driving mechanism 900 may then further move along the second reverse direction. For example, the driving mechanism 900 may move towards the stage 250. Accordingly, the mask structure 340 attached to the second driving mechanism 920 may be detached (or decoupled) from the first carrier 1600 in the second reverse direction and moved in the second reverse direction along the second driving mechanism 920 to deviate from the transfer track 500.

Thereafter, the driving mechanism 900 further moves in the second reverse direction towards the stage 250 by the driving mechanism 900, such that the mask structure 340 attached to the driving mechanism 900 and the stage 250 may be disposed close to each other.

In an embodiment, the second driving mechanism 920 may recognize a position of the stage 250 and adjust an adsorption (or attachment) position between the mask structure 340 and the stage 250. For example, for alignment between the second groove 32 of the frame 300 and the zero electromagnet 25 of the stage 250, an entire position of the driving mechanism 900 including the second driving mechanism 920 may be adjusted.

In an embodiment, the driving mechanism 900 further moves in the second reverse direction toward the stage 250 by the driving mechanism 900, such that the mask structure 340 attached to the driving mechanism 900 and the stage 250 may be disposed closer to each other. Accordingly, the zero electromagnet 25 of the stage 250 may be inserted into the second groove 32 of the frame 300.

Thereafter, the pedestals 28 ascend along the third direction DR3, such that the pedestals 28 and the frame 300 of the mask structure 340 may come into direct contact with each other. For example, the pedestals 28 ascend towards the mask structure 340, such that the pedestals 28 and the frame 300 of the mask structure 340 come into direct contact with each other, and accordingly, the mask structure 340 may be supported by the pedestals 28. For example, a lower surface of the frame 300 may be supported by the pedestals 28.

In an embodiment, in a state where the mask structure 340 is supported by the pedestals 28 and the second driving mechanism 920 as described above, magnetic force may then be generated from the zero electromagnet 25 of the stage 250. For example, after the zero electromagnet 25 of the stage 250 is inserted into the second groove 32 of the frame 300, a current applied to the zero electromagnet 25 is removed (or blocked), such that magnetic force may be generated from the zero electromagnet 25, and the mask structure 340 including the frame 300 may be attached to the stage 250 by such magnetic force from the zero electromagnet 25. Thus, the frame 300 of the mask structure 340 may be attached to (e.g., directly attached thereto) the stage 250.

Thereafter, the second driving mechanism 920 and the mask structure 340 may be decoupled from each other. For example, in an embodiment a current is applied to the zero electromagnet 92 of the second driving mechanism 920, such that the magnetic force from the zero electromagnet 92 may disappear (may be removed), and accordingly, adsorption force by the second driving mechanism 920 may be removed. Accordingly, the mask structure 340 may be maintained in a state in which it is adsorbed to the stage 250 by the zero electromagnet 25 of the stage 250. In other words, the mask structure 340 disposed on the stage 250 may not be supported by the second driving mechanism 920.

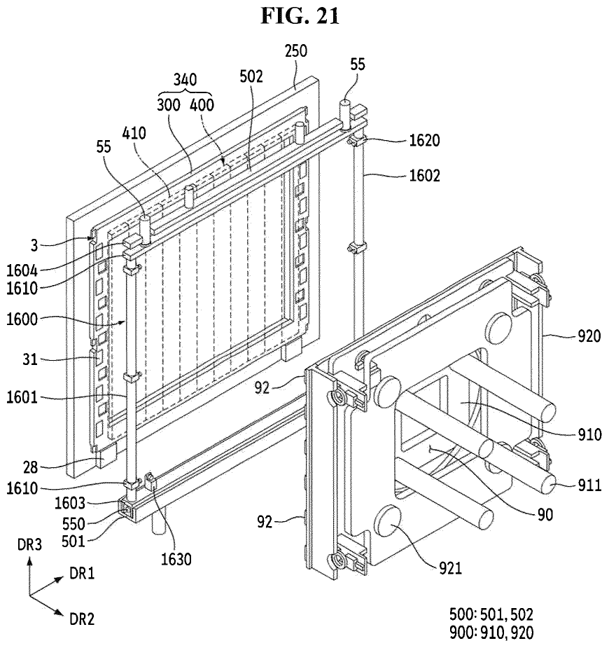

In an embodiment, as illustrated in FIG. 21, the driving mechanism 900 may move in the second direction DR2. For example, the driving mechanism 900 may pass through the opening 88a of the first carrier 1600 along the second direction DR2. In this case, the driving mechanism 900 may be disposed between the transfer track 500 and the second inner wall 102 of the chamber 100 (e.g., in the second direction DR2).

In an embodiment, the pusher 55 may then ascend to move to an original position. Accordingly, the first carrier 1600 (e.g., the first carrier in an empty state) that has delivered the mask structure 340 may ascend to move to the original position. Thereafter, the first carrier 1600 (e.g., the first carrier in the empty state) may pass through the second gate G2 of the chamber 100 along the transfer track 500 (e.g., in the first direction DR1) and then be unloaded to the outside of the chamber 100.

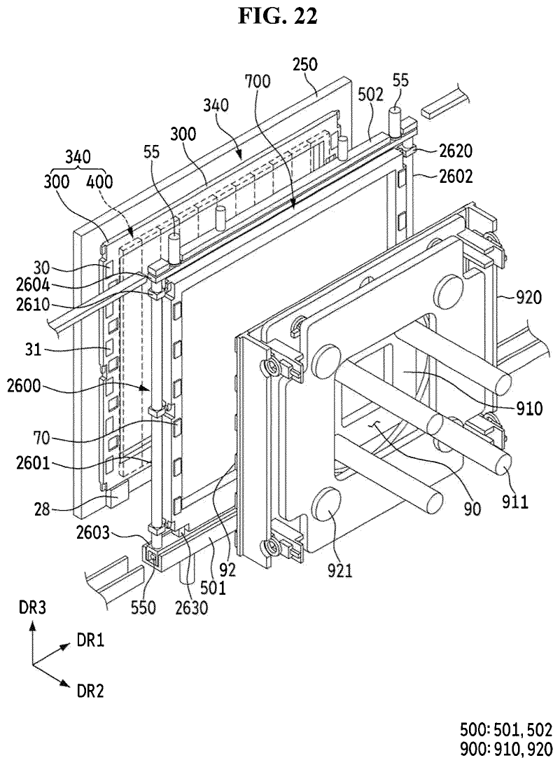

In an embodiment, as illustrated in FIG. 22, the second carrier 2600 loaded with the substrate tray 700 (e.g., the substrate tray 700 on which the substrate 50 for a display device is disposed) may then be loaded into the chamber 100 along the transfer track 500. For example, the second carrier 2600 loaded with the substrate tray 700 may pass through the first gate G1 of the chamber 100 along the transfer track 500 (e.g., in the first direction DR1) and then be loaded into (or disposed inside) the chamber 100. As a specific example, the second carrier 2600 may be disposed in the chamber 100 so that the substrate tray 700 is aligned with the mask structure 340 between the mask structure 340 and the driving mechanism 900.

In an embodiment, the second carrier 2600 may have substantially the same shape as the first carrier 1600 described above. The first carrier 1600 may be a conveyance means for loading the mask structure 340 into the chamber 100, and the second carrier 2600 may be a conveyance means for loading the substrate tray 700 into the chamber 100.

In an embodiment, the substrate tray 700 may then be decoupled from the second carrier 2600 and attached to the driving mechanism 900 by an operation of the pusher 55 and an operation of the driving mechanism 900 as illustrated in FIGS. 9 to 12. For example, the zero electromagnet 92 of the second driving mechanism 920 and the magnetic body 70 of the substrate tray 700 come into direct contact with each other, such that the substrate tray 700 may be attached to the second driving mechanism 920. Each step of this will be described in detail below.

In an embodiment, as the pusher 55 descends to the distance of the first stage, the second carrier 2600 may be supported by the pusher 55 and the lower track 501. Thereafter, the substrate tray 700 may be attached to the second driving mechanism 920 by the zero electromagnet 92 of the second driving mechanism 920. In this case, the second carrier 2600 is supported by the pusher 55 and the lower track 501, and thus, a weight of the second carrier 2600 may not be transmitted to the driving mechanism 900. For example, the driving mechanism 900 may only bear a weight of the substrate tray 700 excluding the second carrier 2600. Accordingly, a fatigue degree of the driving mechanism 900 when adsorbing the substrate tray 700 may be minimized. In an embodiment, the pusher 55 may then descend to the distance of the second stage, and the lower track 501 may descend. Accordingly, restraint of the second carrier 2600 on the substrate tray 700 is released, such that the substrate tray 700 may be supported by the second driving mechanism 920.

Thereafter, the driving mechanism 900 to which the substrate tray 700 is attached may further move in the second reverse direction towards the mask structure 340 on the stage 250 and dispose the substrate tray 700 on the mask structure 340.

In an embodiment, the first driving mechanism 910 may further move along the second reverse direction towards the substrate tray 700. Accordingly, the magnet plate 800 attached to the first driving mechanism 910 may approach the substrate tray 700 or come into direct contact with the substrate tray 700. In this case, the mask structure 340 may be attracted towards the magnets 820 of the magnet plate 800 by magnetic force from the magnet plate 800. Accordingly, close adhesive strength between the substrate 50 on the substrate tray 700 and the mask structure 340 may be increased.

Thereafter, the deposition material from the deposition source 200 may be deposited on the substrate 50 through the pattern holes of the mask structure 340. For example, a deposition process for the substrate 50 may be performed.

In an embodiment, when the first driving mechanism 910 moves during the deposition process described above, the first driving mechanism 910 may move together with the second driving mechanism 920. Similarly, when the second driving mechanism 920 moves during the deposition process, the second driving mechanism 920 may move together with the first driving mechanism 910. For example, when the first driving mechanism 910 is positioned on a movement path along which the second driving mechanism 920 moves, the second driving mechanism 920 and the first driving mechanism 910 may move together. In this case, the first driving mechanism 910 may move together with the second driving mechanism 920 in a state in which it is disposed in the second driving mechanism 920. For example, as illustrated in FIG. 1, the second driving mechanism 920 may have a cross section (e.g., a cross section having a “]” shape) surrounding the first driving mechanism 910, and thus, the first driving mechanism 910 may move together with the second driving mechanism 920 in a state in which it is disposed in the second driving mechanism 920 so as to be surrounded by the second driving mechanism 920.

According to an embodiment, one surface (e.g., a first surface) of the mask structure 340 adsorbed by the zero electromagnet 92 of the second driving mechanism 920 and the other surface (e.g., an opposite second surface) of the mask structure 340 adsorbed by the zero electromagnet 25 of the stage 250 may at least partially overlap each other. For example, the first groove 31 and the second groove 32 of the frame 300 of the mask structure 340 may at least partially overlap each other in the second direction DR2. In an embodiment, the first groove 31 disposed on one surface (e.g., a first surface) of the frame 300 and the second groove 32 disposed on the other surface (e.g., the second surface) of the frame 300 may at least partially overlap each other in the second direction DR2. Accordingly, adsorption areas corresponding to each other among adsorption areas (e.g., first adsorption areas) on one surface (e.g., a first surface) of the frame 300 adsorbed by the zero electromagnets 92 of the second driving mechanism 920 and adsorption areas (e.g., second adsorption area) on the other surface (e.g., a second surface) of the frame 300 adsorbed by the zero electromagnets 25 of the stage 250 may overlap each other in the second direction DR2. Accordingly, positions of the first adsorption areas (e.g., positions of the first adsorption areas in the first direction DR1 and the third direction DR3) when the mask structure 340 is adsorbed through the zero electromagnets 92 of the second driving mechanism 920 and positions of the second adsorption areas (the second adsorption areas corresponding to (or overlapping) the first adsorption areas) (e.g., positions of the second adsorption areas in the first direction DR1 and the third direction DR3) when the mask structure 340 is adsorbed through the zero electromagnets 25 of the stage 250 may be substantially the same as each other. Therefore, a deviation between a position of the mask 400 before the mask structure 340 is installed on the stage 250 and a position of the mask 400 after the mask structure 340 is installed on the stage 250 may be minimized. Accordingly, an alignment degree between the substrate 50 and the mask 400 may be increased. Accordingly, alignment accuracy between pixels of the substrate 50 and the pattern holes of the mask 400 may be increased, such that film formation precision may be increased.

A display device according to an embodiment may be applied to various electronic devices. An electronic device according to an embodiment includes the display device described above, and may further include modules or devices having additional functions in addition to the display device.

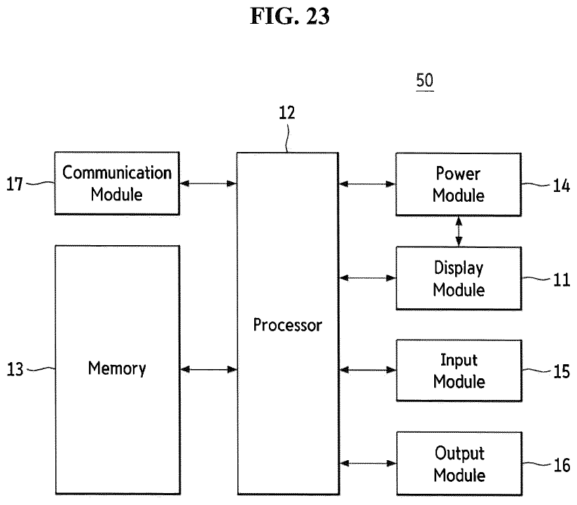

FIG. 23 is a block diagram of an electronic device according to an embodiment. Referring to FIG. 23, an electronic device 50 according to an embodiment may include a display module 11, a processor 12, a memory 13, and a power module 14. The electronic device 50 may further include an input module 15, a non-image output module 16, and/or a communication module 17.

The electronic device 50 may output various information in the form of an image through the display module 11. When the processor 12 executes an application stored in the memory 13, image information provided by the application may be provided to a user through the display module 11. The power module 14 may include a power supply module such as a power adapter or a battery device and a power conversion module converting power supplied by the power supply module to generate power necessary for an operation of the electronic device 50. The input module 15 may provide input information to the processor 12 and/or the display module 11. The non-image output module 16 may serve to receive information other than an image received from the processor 12, such as sound information, haptic information, and light emitting information, and provide the received information to the user. The communication module 17 is a module in charge of transmitting and receiving information between the electronic device 50 and an external device, and may include a receiving unit and a transmitting unit.

At least one of the respective components of the above-described electronic device 50 may be included in the display device according to the above-described embodiments. In addition, some of individual modules functionally included in one module may be included in the display device, and the others of the individual modules may be provided separately from the display device. For example, in an embodiment the display device may include the display module 11, and the processor 12, the memory 13, and the power module 14 may be provided in the form of other devices within the electronic device 50 rather than the display device.

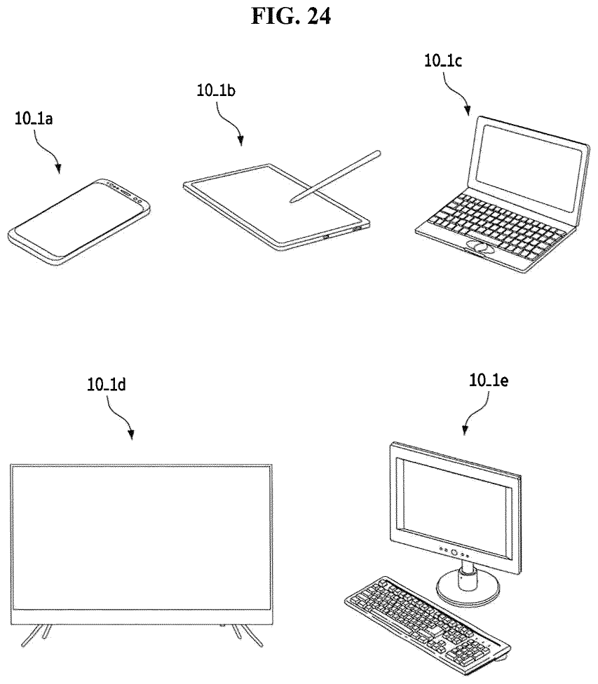

FIGS. 24 to 26 are schematic views of electronic devices according to various embodiments. FIGS. 24 to 26 illustrate examples of various electronic devices to which a display device 10 according to embodiments is applied.

FIG. 24 illustrates a smartphone 10_1a, a tablet personal computer (PC) 10_1b, a laptop computer 10_1c, a television (TV) 10_1d, and a monitor 10_1e for a desktop computer as examples of the electronic devices.

The smartphone 10_1a may include an input module such as a touch sensor and a communication module in addition to the display module 11. The smartphone 10_1a may process information received through the communication module or other input modules and display the processed information through the display module of the display device.

Each of the tablet PC 10_1b, the laptop computer 10_1c, the TV 10_1d, and the monitor 10_1e for a desktop computer may include a display module and an input module, similar to the smartphone 10_1a, and may further include a communication module in some cases.

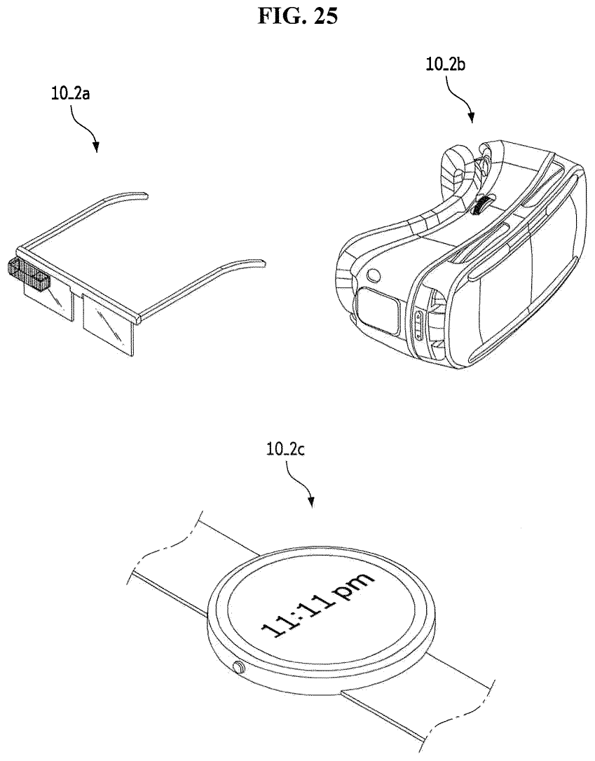

FIG. 25 illustrates a case where an electronic device including a display module is applied to a wearable electronic device. The wearable electronic device may be a smart glasses 10_2a, a head mounted display 10_2b, a smart watch 10_2c, or the like.

The smart glasses 10_2a and the head mounted display 10_2b may include a display module emitting a display image and a reflector reflecting the emitted display image and providing the emitted display image to user's eyes, and accordingly, may provide a virtual reality screen or an augmented reality screen to the user.

The smart watch 10_2c may include a biometric sensor as an input device, and may provide biometric information recognized through the biometric sensor to the user through the display module.

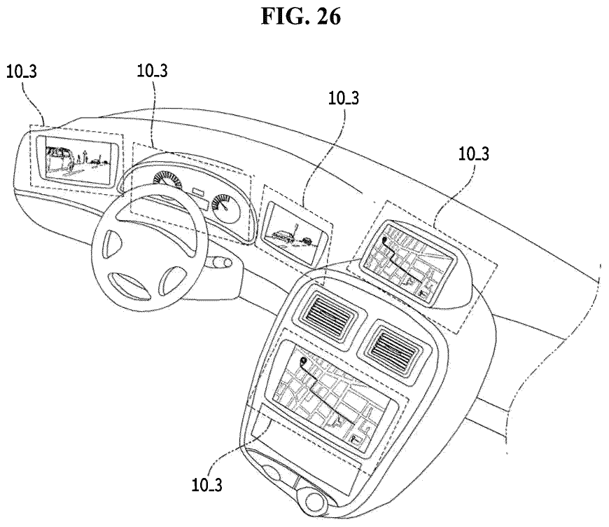

FIG. 26 illustrates a case where an electronic device including a display module is applied to a vehicle. For example, an electronic device 10_3 may be applied to an instrument board, a center fascia, or the like, of the vehicle or applied to a center information display (CID) disposed on a dashboard of the vehicle, a room mirror display substituting for a side-view mirror, or the like. However, embodiments of the present disclosure are not necessarily limited thereto and the electronic device may be various different small-sized, medium-sized or large-sized electronic devices.

In concluding the detailed description, those skilled in the art will appreciate that many variations and modifications can be made to the described embodiments without substantially departing from the principles of the present invention. Therefore, the described embodiments of the present disclosure are used in a generic and descriptive sense only and not for purposes of limitation.

What is claimed is:

1. A deposition equipment for display devices, comprising:
a chamber including a first gate and a second gate;
a deposition source disposed in the chamber;
a stage disposed on the deposition source;
a mask structure disposed on the stage, the mask structure including a frame and a mask disposed on the frame;
a driving mechanism disposed on the mask structure; and
a transfer track having a first portion disposed inside the chamber and a second portion disposed outside the chamber, the transfer track extending through the first gate of the chamber and the second gate of the chamber,
wherein a first adsorption area of a first surface of the frame adsorbed by the driving mechanism and a second adsorption area of an opposite second surface of the frame adsorbed by the stage at least partially overlap each other.

2. The deposition equipment for display devices of claim 1, wherein the first adsorption area of the frame and the second adsorption area of the frame at least partially overlap each other in a thickness direction of the frame.

3. The deposition equipment for display devices of claim 2, wherein the frame includes:
a first groove defining the first adsorption area; and
a second groove defining the second adsorption area.

4. The deposition equipment for display devices of claim 3, wherein:
the first groove is disposed on the first surface of the frame; and
the second groove is disposed on the second surface of the frame.

5. The deposition equipment for display devices of claim 4, wherein the first groove and the second groove at least partially overlap each other in the thickness direction of the frame.

6. The deposition equipment for display devices of claim 4, wherein the first groove and the second groove have a same size as each other.

7. The deposition equipment for display devices of claim 4, wherein:
the first groove has a shape that is recessed from the first surface of the frame towards the second surface of the frame, and
the second groove has a shape that is recessed from the second surface of the frame towards the first surface of the frame.

8. The deposition equipment for display devices of claim 1, wherein:
the driving mechanism includes a first electromagnet disposed to correspond to the first adsorption area of the frame, and
the stage includes a second electromagnet disposed to correspond to the second adsorption area of the frame.

9. The deposition equipment for display devices of claim 8, wherein each of the first electromagnet and the second electromagnet comprises a zero electromagnet.

10. The deposition equipment for display devices of claim 8, wherein:
the first electromagnet is disposed to correspond to a first groove defining the first adsorption area of the frame; and
the second electromagnet is disposed to correspond to a second groove defining the second adsorption area.

11. The deposition equipment for display devices of claim 1, wherein:
the first adsorption area is disposed on an edge of the first surface of the frame; and
the second adsorption area is disposed on an edge of the second surface of the frame.

12. The deposition equipment for display devices of claim 1, wherein the frame includes a magnetic material.

13. The deposition equipment for display devices of claim 1, wherein the transfer track includes:
a lower track; and
an upper track facing the lower track.

14. The deposition equipment for display devices of claim 13, further comprising a carrier transferring the mask structure along the transfer track, the carrier is positioned between the lower track and the upper track.

15. The deposition equipment for display devices of claim 14, wherein the carrier includes:
a first bar;
a second bar disposed to face the first bar;
a third bar disposed on the lower track;
a fourth bar disposed on a lower side of the upper track and disposed to face the third bar;
an opening surrounded by the first bar, the second bar, the third bar, and the fourth bar;
a first support member extending from the first bar towards the second bar;
a second support member extending from the second bar towards the first bar; and
a third support member extending from the third bar towards the fourth bar.

16. The deposition equipment for display devices of claim 15, wherein the first support member includes:
an extension portion extending from the first bar; and
a projection rotatably connected to a first side of the extension portion.

17. The deposition equipment for display devices of claim 16, wherein the third support member includes:
an extension portion extending from the third bar;
a protrusion portion disposed on a first side of the extension portion; and
a projection rotatably disposed on a first side of the protrusion portion.

18. The deposition equipment for display devices of claim 15, further comprising a pusher disposed to face the fourth bar through an opening of the upper track and movable towards the fourth bar.

19. A method of deposition for a display device, comprising:
disposing a deposition source, a stage, a driving mechanism, a pusher, and a transfer track inside a chamber between a first inner wall of a chamber and a second inner wall of the chamber;
moving a carrier loaded with a mask structure including a mask along the transfer track to load the carrier into the chamber;
adsorbing a first adsorption area of a frame of the mask structure by a first electromagnet of the driving mechanism;
decoupling the mask structure from the carrier;
moving the driving mechanism that the mask structure is attached thereto towards the stage; and
adsorbing a second adsorption area of the frame of the mask structure by a second electromagnet of the stage,
wherein the first adsorption area of the frame and the second adsorption area of the frame at least partially overlap each other.

20. An electronic device comprising:
a display device,
wherein a substrate of the display device includes an organic material formed using a deposition equipment,
the deposition equipment includes:
a chamber having a first gate and a second gate;
a deposition source disposed in the chamber;
a stage disposed on the deposition source;
a mask structure disposed on the stage, the mask structure including a frame and a mask disposed on the frame;
a driving mechanism disposed on the mask structure; and
a transfer track having a first portion disposed inside the chamber and a second portion disposed outside the chamber, the transfer track extending through the first gate of the chamber and the second gate of the chamber,
the mask structure includes a frame and a mask disposed on the frame, and
a first adsorption area of a first surface of the frame adsorbed by the driving mechanism and a second adsorption area of an opposite second surface of the frame adsorbed by the stage at least partially overlap each other.
